(19) United States
(12) Patent Application Publication
(10) Pub. No.: US 2021/0193467 A1
(43) Pub. Date: Jun. 24, 2021

(54) THROUGH-GATE CO-IMPLANT SPECIES TO CONTROL DOPANT PROFILE IN TRANSISTORS

(71) Applicant: TEXAS INSTRUMENTS INCORPORATED, Dallas, TX (US)

(72) Inventors: MAHALINGAM NANDAKUMAR, RICHARDSON, TX (US); BRIAN EDWARD HORNUNG, RICHARDSON, TX (US); LI JEN CHOI, MILPITAS, CA (US)

(21) Appl. No.: 17/119,569

(22) Filed: Dec. 11, 2020

Related U.S. Application Data
(60) Provisional application No. 62/950,975, filed on Dec. 20, 2019.

(51) Int. Cl. H01L 21/265; H01L 29/10; H01L 29/167; H01L 29/78; H01L 29/66; H01L 21/324; H01L 21/225

(52) U.S. Cl. CPC H01L 21/2652; H01L 29/1083; H01L 29/167; H01L 21/2253; H01L 29/66537; H01L 29/66492; H01L 21/324; H01L 29/7833

(57) ABSTRACT

In a described example, an integrated circuit (IC) includes a metal oxide semiconductor (MOS) transistor formed in a semiconductor substrate. The transistor includes a gate structure formed over a surface of the substrate and source and drain regions having a first conductivity type formed in the substrate on both sides of the gate structure. A well region having a second opposite conductivity type is between the source and drain regions under the gate structure. The well region includes a well dopant and a through-gate co-implant species. The well dopant and the co-implant species have a retrograde profile extending from the surface of the substrate into the well region.

### CROSS-REFERENCE TO RELATED APPLICATION

This application claims priority from U.S. Provisional Patent Application Ser. No. 62/950975, filed Dec. 20, 2019, and entitled LIGHTLY-DOPED DRAIN WITH THROUGH-GATE CARBON CO-IMPLANT, which is incorporated herein by reference in its entirety.

### TECHNICAL FIELD

This description relates to transistors and methods of making transistors with a through-gate co-implant species implant to control dopant profile.

### BACKGROUND

Mismatch may occur locally and globally among device parameters during fabrication of devices on a die. For example, transistor mismatch may occur in variability in threshold voltage, maximum transconductance and drain current. As one example, variability in doping profiles can affect transistor mismatch. A common approach to improve mismatch is to increase the area (e.g., width and/or length) of transistor devices on the die. However, this approach results in larger devices and reduced device density on the die. Accordingly, an approach is needed to improve mismatch that also allows for smaller devices and increased device density for integrated circuits.

### SUMMARY

In a described example, an integrated circuit (IC) includes a metal oxide semiconductor (MOS) transistor formed in a semiconductor substrate. The transistor includes a gate structure formed over a surface of the substrate and source and drain regions having a first conductivity type formed in the substrate on both sides of the gate structure. A well region having a second opposite conductivity type is between the source and drain regions under the gate structure. The well region includes a well dopant and a through-gate co-implant species. The well dopant and the co-implant species have a retrograde profile extending from the surface of the substrate into the well region.

Another described example relates to a method of forming an integrated circuit. The method includes forming a gate structure on a surface of a substrate and forming source/drain regions in the substrate on either side of the gate structure. A dopant is into the substrate to establish a channel region. A co-implant species is implanted through the gate structure into the substrate. The method also includes annealing after implanting both the dopant and the co-implant species to provide a retrograde profile of the dopant in the substrate beneath the gate structure.

In a further described example, an integrated circuit (IC) includes first and second transistors formed in or over a semiconductor substrate. The first transistor includes a first source region and a first drain region both having a first conductivity type formed in the substrate. The first transistor also includes a first gate structure formed over a surface of the substrate between the first source region and the first drain region, the first gate structure having a long axis oriented laterally over the substrate in a first direction. The first transistor also includes a first well region having a second opposite conductivity type under the first gate structure and between the first source region and the first drain region. The first well region includes a well dopant and a first co-implant species, the well dopant and the first co-implant species having a retrograde profile extending from the surface of the substrate into the first well region. The second transistor includes a second source region and a second drain region both having the first conductivity type formed in the substrate. The second transistor also includes a second gate structure formed over the surface of the substrate between the second source region and the second drain region. The second gate structure has a long axis oriented laterally over the substrate in a second direction about orthogonal to the first direction. The second transistor also includes a second well region under the second gate structure and between the second source region and the second drain region. The second well region includes the well dopant and a second co-implant species, the well dopant and the second co-implant species having a retrograde profile extending from the surface of the substrate into the first well region.

### BRIEF DESCRIPTION OF THE DRAWINGS

FIG. 1 is a cross-sectional view of an example transistor.

FIG. 2 is a graph depicting the dopant profile in the transistor of FIG. 1.

FIG. 3 is a flow diagram depicting an example method of making a transistor.

FIGS. 4-9 are cross-sectional views depicting examples of the transistor at various stages of fabrication according to the method of FIG. 3.

FIG. 10 is a top elevation of an example non-core transistor.

FIG. 11 is a cross-sectional view of the transistor of FIG. 10 taken along line 11-11 showing an example of through-gate species implantation.

FIG. 12 is a top elevation of an example core transistor.

FIG. 13 is a cross-sectional view of the transistor of FIG. 12 taken along line 13-13 showing examples of halo implantation and through-gate species implantation.

FIG. 14 is a cross-sectional view of another example of a transistor showing through-gate implantation of a diffusion control species.

FIG. 15 is a cross-sectional view of yet another example of a transistor showing through-gate implantation of a diffusion control species.

FIG. 16 is a graph depicting mismatch versus threshold voltage for transistors fabricated according to different methods.

FIG. 17 is a graph depicting mismatch versus area^{-1/2} for different size non-core transistors fabricated according to different methods.

FIG. 18 is a graph depicting body effect versus threshold voltage for transistors fabricated according to different methods.

FIG. 19 is another graph depicting mismatch versus area^{-1/2} for different size core transistors fabricated according to different methods.

### DETAILED DESCRIPTION

Example embodiments relate to transistors and integrated circuits that include transistors that exhibit improved mismatch. For example, one or more metal oxide semiconductor (MOS) transistor includes dopant and through-gate co-implant species in a channel region of the substrate located beneath a gate structure between drain and source regions. The dopant species may include a well dopant and a channel dopant. The co-implant species is implanted with sufficient energy to pass through the gate structure (e.g., polysilicon and gate dielectric layers) and into the substrate. During fabrication, the co-implant species controls (e.g., retards) diffusion of the dopant species to establish a retrograde dopant profile in response to annealing. In an example, the retrograde profile provides a dopant concentration that increases from the surface of the substrate to a location having a peak concentration, which is spaced from the surface of the substrate, and then decreases from the location having the peak concentration further away from the surface of the substrate. The retrograde profile of the dopant concentration may provide for improved (e.g. reduced) mismatch in transistor parameters as compared to existing approaches. The improvements in mismatch may be local (e.g., across a given die or region of die) and/or extend globally across batches.

In some examples, the transistor may include source/drain extension regions formed on both sides of the gate structure. The transistor also may include halo regions formed on both sides of the gate structure. The approach disclosed herein may be used to fabricate N-type MOS transistors as well as P-type MOS transistors, including core transistors (e.g., transistors in digital logic gates) and non-core MOS transistors (e.g., analog-friendly or I/O transistors).

For example, “core” transistors are generally used for logic gates (Boolean logic gates (i.e., AND, OR, NOT, XOR, XNOR) on the IC and typically comprises smaller geometry devices, e.g. shorter gate length, for faster operation. Core transistors may also include a thinner gate dielectric (in terms of equivalent oxide thickness, or EOT) to operate at a relatively low power supply voltage. “Non-core” transistors, such as I/O transistors, may be designed to interact with external devices and typically comprise larger geometry (e.g. gate length) devices that include a thicker gate dielectric for operation at higher voltages as compared to the core transistors on the IC. For example, I/O and analog-friendly transistors may sustain higher voltages (e.g., 1.2-10 volts), such as 1.8 volts, 2.5 volts or 3.3 volts and have a threshold voltage of about 0.2 to 1.0 volts, whereas the core transistors may sustain up to only 1.7 volts and their threshold voltages may be about 0.1 to 0.5 volts. Because analog-friendly transistors may have a longer gate length, and longer channel, than core transistors, greater boron diffusion in NMOS devices may occur in the absence of through-gate diffusion control implants described herein. While the through-gate diffusion control implants disclosed herein are described with respect to core and non-core transistors, the disclosed principles may be applicable to benefit other transistor technologies.

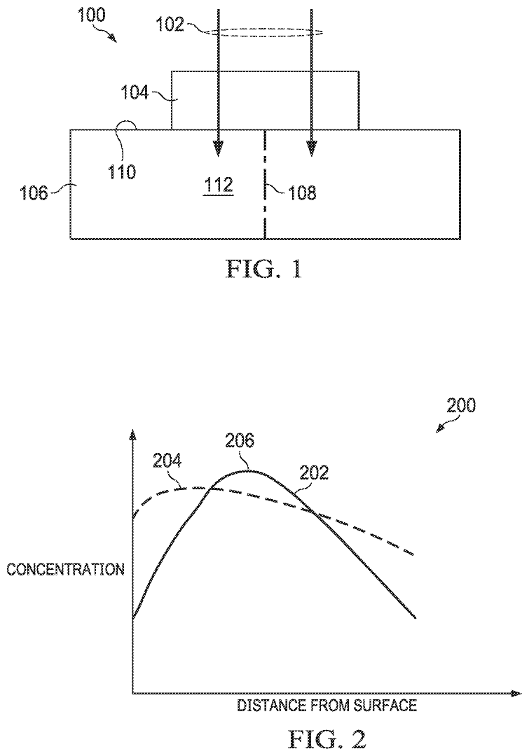

FIG. 1 depicts an example of part of a MOS transistor 100 demonstrating implantation 102 of a through-gate co-implant species. As used herein the term “co-implant species” is defined as including carbon and/or nitrogen and/or fluorine. The transistor 100 includes source/drain regions that are not shown. The transistor 100 also includes a gate structure 104 and a well region 112 appropriately doped, e.g. P-type for an NMOS transistor and N-type for a PMOS transistor. The well region 112 may include a well dopant that is relatively uniformly distributed within the well region 112, and a channel dopant that is relatively localized to the portion of the well region 112 below the gate structure 104 and near the surface 110. The co-implant species is implanted at sufficient energy to pass through the gate structure 104 and into the well region 112 to affect the characteristics of a channel region located beneath the gate structure and between the unpictured drain and source regions. The implantation energy level may vary depending on the thickness of the gate structure 104 and which dopant species is used, such as ranging from 10 keV to about 100 keV. In an example, the through-gate co-implant species includes one of carbon, nitrogen or fluorine. By way of example, where the gate structure 104 (e.g., comprising polysilicon) has a thickness from approximately 70 nm to approximately 200 nm and for tilt angles of the implantation 102 in the range of approximately 0-7 degrees, the implant energy range for carbon may range from 18 keV to 80 keV, nitrogen 20 keV to 100 keV, and fluorine from 30 keV to 110 keV. In some examples, higher tilt angles (e.g., up to approximately 45 degrees) can be used, in which implant energies would be increased correspondingly to achieve the same implant depth in the substrate. Example implant doses for the co-implant species are approximately 1E12 ions/cm² to approximately 2E14 ions/cm².

After the implantation 102 the co-implant species has a concentration profile within the well region 112 that varies with depth. A peak concentration of the co-implant species may be located close to a surface 110 of the substrate 106, and the remaining profile may overlap most if not all of the concentration profile of the channel dopant. This enables the co-implant to control the diffusion of the channel dopant during anneal, which results in a desired retrograde profile of the channel dopant (see, e.g., FIG. 2 and discussion below). For example, the through-gate co-implant species is expected to control (e.g., retard) diffusion of the channel dopant. The channel dopant may be implanted through the gate structure 104, or alternatively may be implanted into the well region 112 prior to forming the gate structure 104. In an example where the transistor 100 is N-type MOS transistor, the channel dopant includes a P-type dopant, such as boron. In an example where the transistor 100 is P-type MOS transistor, the dopant includes an N-type dopant, such as phosphorous.

In response to annealing (e.g., an ultra-high temperature anneal, such as rapid thermal anneal), the co-implant species may control the diffusion of the dopant species to establish a retrograde profile within the substrate 106 along a direction, demonstrated by virtual line 108, which is orthogonal to a surface 110 of the substrate. The channel dopant is also activated responsive to the anneal.

FIG. 2 depicts a graph 200 of concentration as a function of distance from a surface for a concentration 202 of the well dopant and channel dopant, and a concentration 204 of a through-gate diffusion control species. As shown, the concentration 202 depicts retrograde dopant profile as a function of distance from the surface relative to the virtual line 108 of FIG. 1. As illustrated, the concentration 202 increases from the surface of the substrate to a peak concentration 206 at a location that is spaced from the surface of the substrate, and then decreases from the peak concentration at distances further away from the surface of the substrate. In an example, the peak concentration 206 is greater than 1.5 times the concentration at the surface. In the example shown in FIG. 2, a peak of the concentration 204 of the through-gate co-implant species occurs closer to the surface than the concentration 202 of the well dopant.

A transistor that is made to include a retrograde profile of the channel dopant concentration, as described herein, may exhibit higher body effect. The threshold voltage of such a transistor may not depend primarily on the surface doping but may rather be dominated by the concentration depth gradient of the channel dopant in the channel region. The channel dopant concentration depth gradient may in turn be well controlled by the co-implant. This is expected to result in significant reduction in local threshold voltage mismatch. Additionally, the retrograde profile of the channel dopant may also lower both local (cross-die) and global (cross-wafer) variability of transistor current-voltage (IV) curves and related parameters of the transistor, such as threshold voltage, drive current, and transconductance (gₘ). Thus smaller transistor devices on the IC die may operate within desired device specifications.

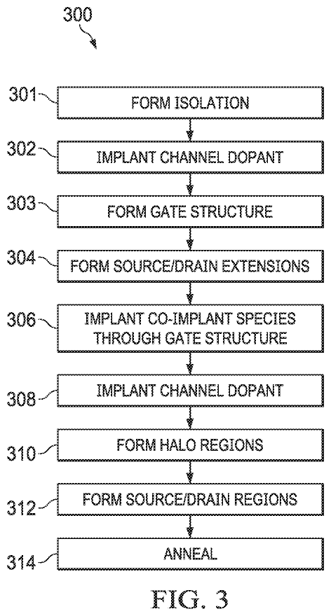

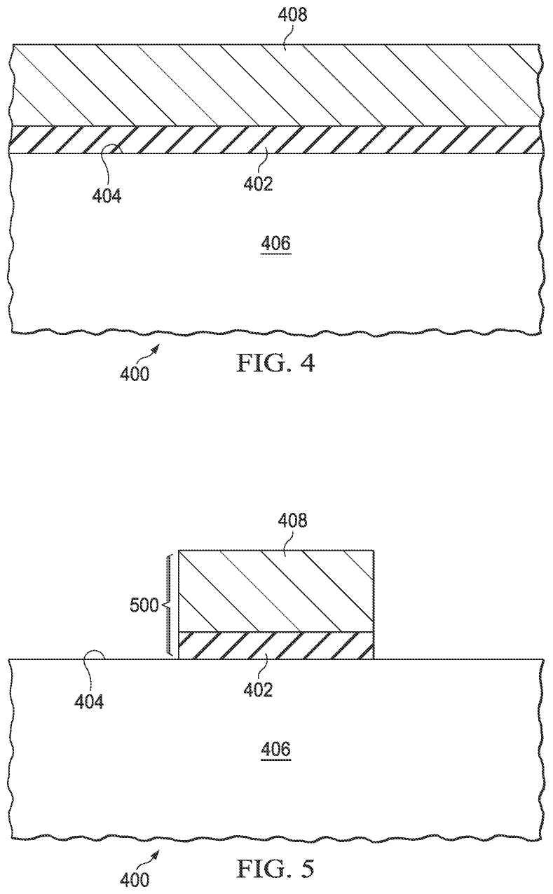

Turning now to FIG. 3, an example method 300 is presented for forming one or more transistors on a semiconductor substrate. While the actions described in the method 300 are presented in the illustrated order, the disclosure contemplates implementing the described actions in different orders consistent with the constraints of semiconductor device manufacturing. FIGS. 4-9 are cross-sectional views depicting examples of a transistor 400 at various stages of fabrication according to the method 300. The method 300 may be used to fabricate any transistor device described herein (e.g., transistors 100, 400, 1000, 1200, 1400 or 1500).

The method 300 begins at 301 in which an isolation structure is formed. As an example, the isolation structure is a shallow trench isolation (STI) structure formed within the substrate. In other examples, other types of isolation technologies may be used to provide isolation, such as field oxidation regions, e.g. local oxidation of silicon (LOCOS) regions, or implanted isolation regions. The isolation structure may laterally bound an active region within which the transistor 400 is formed.

At 302, well and channel dopants are implanted into the substrate within the active region. The well dopant sets the default doping type and level of the active region e.g. P-type for an NMOS device or N-type for a PMOS device. The channel dopant is implanted to set threshold voltage operation over the substrate and determine the depth of the channel during operation. As described for the well dopant, the channel dopant can include one or more of P-type dopants (e.g., boron, indium or other dopant species), or N-type dopants (e.g., phosphorous, antimony, or arsenic) according to whether an NMOS or PMOS transistor is being fabricated.

In an example, boron is implanted to form the well region at 302, and indium is implanted as the channel dopant. Indium may be implanted with a dose within a range between about 1E12 ions/cm² and about 1E13 ions/cm² implanted at an energy within a range between about 50 keV and about 150 keV. As another example, boron may be implanted as the channel dopant, such as a dose of boron (e.g. ¹¹B) within a range between about 1E12 ions/cm² and about 8E12 ions/cm² implanted at an energy level within a range between about 10 keV and about 20 keV. Other dopants may be implanted at other doses and energy levels into the channel region as part of the method 300.

At 303, a gate structure is formed over a surface of a substrate. For example, as shown in FIG. 4, a gate dielectric layer 402 is formed over a surface 404 of a substrate 406. The layer(s) of gate dielectric layer 402 can include a high-k dielectric material, for example. As used herein, a “high-k” dielectric has a relative dielectric permittivity, or k-value, greater than 7.8, which is at least about twice the k-value of conventional silica. A gate electrode layer 408 is formed over the gate dielectric layer 402, such as by depositing polysilicon, SiGe or metal. In some examples, such as in the case that core and non-core transistors are being formed on the same substrate, the gate dielectric layer 402 can be formed on the substrate surface 404 as one or more different layers that vary in thickness and/or composition across the substrate 406 to implement devices having different supply voltage tolerances (e.g., core transistors and non-core transistors). The substrate 406 may generally include any type of semiconductor body (e.g., silicon, SiGe, SOI), such as a semiconductor wafer or one or more die on a wafer, as well as any other type of semiconductor and/or epitaxial layers grown thereon and/or otherwise deposited on semiconductor.

The gate electrode layer 408 and the gate dielectric layer 402 are patterned and etched to form gate structure 500, such as shown in FIG. 5. The gate structure 500 includes gate dielectric 502 and gate electrode 508. The patterning of the gate electrode layer 408 and the gate dielectric layer 402 (as with all masking and/or patterning disclosed herein) may be performed in any suitable manner, such as through lithographic techniques, for example, where lithography broadly refers to processes for transferring one or more patterns between various media. In lithography, for example, a light sensitive resist coating is formed over one or more layers to which a pattern is to be transferred. The resist coating is then patterned by exposing it to one or more types of radiation or light, which (selectively) passes through an intervening lithography mask containing the pattern. The light causes exposed or unexposed portions of the resist coating to become more or less soluble, depending on the type of resist used. A developer is then used to remove the more soluble areas leaving the patterned resist. The patterned resist can then serve as a mask for the underlying layer or layers that can be selectively treated (e.g., etched). In some examples, a metal material may be used to form the gate electrode 508.

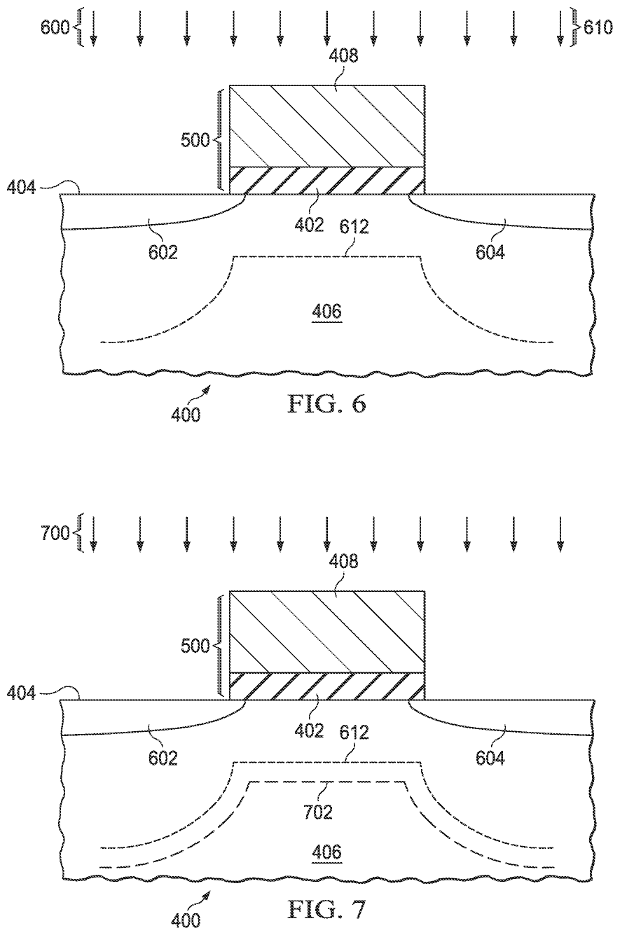

At 304, the method includes forming source/drain extension regions 602, 604 adjacent the gate structure 500. For example, as shown in FIG. 6, source/drain extension regions 602, 604 are formed by implementing a lightly doped drain (LDD) implant 600. For the example of making an NMOS transistor, the LDD implant 600 may implant an N-type dopant including one or more of arsenic, phosphorous and antimony. For a PMOS transistor, the LDD implant may be a P-type dopant including one or more of boron, aluminum and indium. During the implantation, the gate structure operates as a mask to block the implanted dopants so that the source/drain extension regions are formed in the substrate 406 on either side of the gate structure 500.

At 306, a through-gate co-implant species is implanted through the gate structure into the substrate. In one example, this implantation is performed along with (e.g., at the same masking level) forming the source/drain extensions 602, 604 at 304, specifically using the same implant mask so as to selectively affect core and analog-friendly transistors that share the drain extension implant accordingly. In another example, the implantation at 306 is performed along with (at the same masking level) both forming the source/drain extensions at 304 and a halo implant at 310 so as to selectively impact those components.

As a further example, as also shown in FIG. 6, a through-gate co-implant species 610 is implanted with sufficient energy to pass through the gate structure to form a profile qualitatively described by a peak concentration profile 612. The implantation energy may be set according to the thickness of the gate structure 500, such as ranging from about 10 keV to about 80 keV. As an example, for a gate structure having a thickness of 150 nm, the co-implant species 610 may be implanted with an energy ranging from about 30 keV to about 60 keV. The co-implant can also be implanted through the LDD source/drain extension regions 602, 604 more deeply into the substrate 406. Thus the peak concentration of the co-implant species 610 is shallower below the gate structure 500 and deeper under the LDD source/drain extension regions 602, 604. The co-implant species is a dopant control species, which may include one or more of carbon, nitrogen or fluorine, to control diffusion of a channel dopant that is implanted (at 302 and/or 308) in a well region within the substrate 406 and modifies the channel region of the device. Unlike an electrically active dopant, the co-implant species is expected to have little or negligible effect on the electrical conductivity of the channel region such as a dissociated dopant would have.

As shown at 308, a channel dopant species is implanted into the substrate. For example, FIG. 7 depicts implantation of a channel dopant 700 to form a peak concentration profile 702 in the substrate 406 beneath gate structure 500. As for the peak concentration profile 612, the peak concentration profile 702 qualitatively describes the depth of maximum concentration of the channel dopant, e.g. shallower under the gate structure 500 and deeper under the LDD source/drain extension regions 602, 604. The channel dopant 700 is selected according to the type of MOS transistor being fabricated. For the example of making an NMOS transistor, the channel dopant 700 may be a P-type dopant including one or more of boron, aluminum and indium. By way of example, the gate electrode 508 (FIG. 5) (e.g., polysilicon) may have a thickness in a range between approximately 70 nm and approximately 200 nm, and for tilt angles in the range of approximately 0-7 degrees. As a further example, boron may be implanted at an energy of approximately 17 keV to approximately 80 keV for a dose of approximately 1E12 ions/cm² to approximately 1E14 ions/cm². For a PMOS transistor, the channel dopant 700 may be an N-type dopant including one or more of phosphorous, arsenic and antimony. Additionally, the channel dopant 700 is implanted at an angle, which can range from about 0 to about 45 degrees with respect to the gate. The particular angle for implanting the channel dopant 700 may be set according to the type of transistor (e.g., core or non-core transistor).

In some examples, the channel dopant 700 is implanted at 308 in the same masking step (e.g., using the same patterned layer of photoresist) as used to implant the through-gate diffusion control species at 306. In one example, source/drain regions 902/904 (312 and FIG. 9) are formed before implanting the co-implant species 610 (at 306). In another example, halo regions 802/804 are formed after implanting the co-implant species 610, such as shown in FIG. 7. Thus, the through-gate diffusion control implant (demonstrated at 610) can be performed anywhere in the process flow 300 with or without a mask depending on a desired impact on the other components of the transistor being formed. In yet another example, the second channel implant at 308 may be omitted.

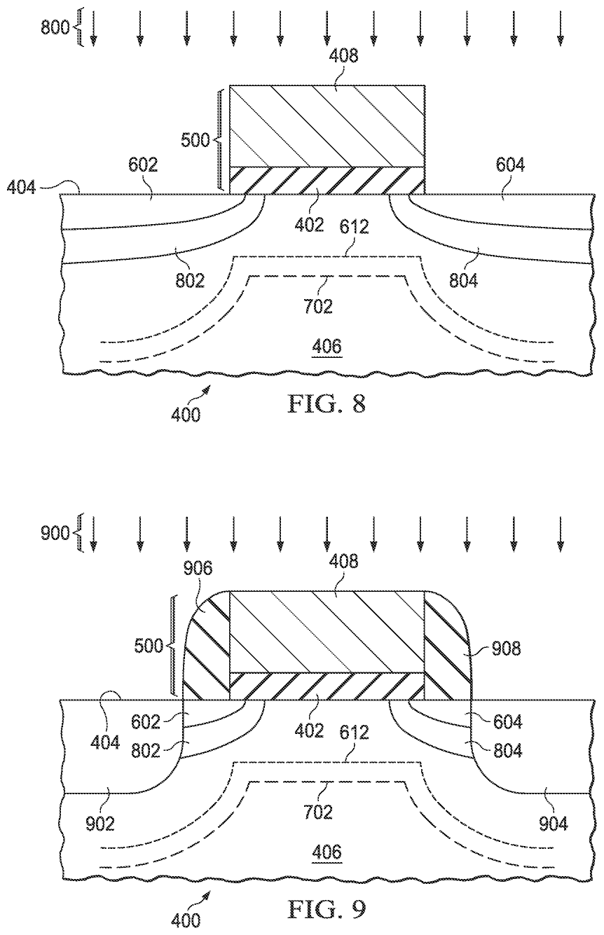

At 310, halo regions are formed in the substrate. For example, as shown in FIG. 8, one or more implants 800 may be utilized, for example, to selectively locate dopants within the substrate 406 to form the halo regions 802, 804. Similar to the source/drain extension regions 602, 604, the halo regions 802, 804 may be formed by implanting at least one dopant that is selected according to the type of MOS transistor. For the example of making an NMOS transistor, the halo implant may be a P-type dopant including one or more of boron, aluminum and indium. For a PMOS transistor, the implant may be an N-type dopant including one or more of phosphorous, arsenic and antimony. For example, for an NMOS transistor boron may be implanted with a dose of 5E12-5E13 cm⁻² at an energy of 8-25 keV, while for a PMOS transistor phosphorous may be implanted with a dose of 5E12-5E13 cm⁻² at an energy of 20-70 keV. The halo implants may be implanted at an angle (e.g., ranging from 0 to 45 degrees) with respect to the substrate surface 404 to form the halo regions 802 and 804. Additionally, dopant atoms are selectively directed into the substrate 406 during halo implantation 800 because the gate structure 500 operates as a mask to block some dopant atoms. In some examples, the halo regions can be formed before the LDD source/drain extension regions 602, 604 are formed.

In one example, the method 300 includes implanting dopants for the source/drain extensions 602/604 (at 304), through-gate co-implant species (at 306), channel dopants (at 308) and halo regions (at 310) using the same masking level. In other examples consistent with this description, separate masking levels can be used for implanting drain extensions, through-gate diffusion control implants and/or halos for both non-core and core transistors.

At 312, the method includes forming source/drain regions 902, 904 in the substrate 406. For example, as shown in FIG. 9, a source/drain dopant 900 is implanted along the sides of the gate structure 500 to form the source/drain regions 902, 904. The source/drain regions 902, 904 are formed on either side of the gate structure 500 by directing the dopant into select locations within the substrate 406. In some examples, the gate structure 500 may include sidewall spacers 906 and 908 (e.g., a dielectric material, such as an oxide or nitride) to space the source/drain dopant from the gate structure 500. In this way, the source/drain regions 902, 904 are adjacent and laterally spaced apart from the gate structure 500 further than the source/drain extension regions 602, 604. For the example of making an NMOS transistor, the source/drain regions 902, 904 may be an N-type dopant including one or more of phosphorous, arsenic and antimony. For a PMOS transistor, the source/drain regions 902, 904 may be a P-type dopant including one or more of boron, aluminum and indium. The peak concentration profile 612 of the through-gate co-implant species 610 is spaced apart from the substrate surface 404 by a first distance directly under the gate structure 500, and spaced apart from the substrate surface 404 by a second greater distance directly below the source/drain regions 902, 904.

After the channel dopant and through-gate co-implant species have been implanted in the substrate 406 beneath the gate structure 500, at 314, the method 300 includes annealing to establish a retrograde profile of the channel dopant in the substrate 406 beneath the gate structure 500. The annealing also activates the channel dopant within the substrate. As described herein, the presence of the through-gate co-implant species 610 in the well region beneath the gate structure 500 controls migration of the dopant during anneal (at 314) to effect the desired retrograde profile of the dopant concentration. The retrograde dopant profile beneath the gate structure enables threshold voltage mismatch to be reduced. By reducing threshold voltage mismatch across devices, the sizes of transistors across a die can be reduced which enables a corresponding increase in device density compared to many existing approaches.

In an example, the annealing at 314 may include an ultra-high temperature (UHT) anneal that operates to control conditions to provide a peak anneal temperature of between approximately 1000° C. and 1400° C. and an anneal time at the peak temperature of generally less than 10 seconds, and typically less than 1 second. The UHT annealing may be implemented as a rapid thermal anneal (RTA), flash lamp anneal, or laser anneal. In the case of a laser anneal, the time can be reduced to less than 10 msec, such as between about 0.1 msec and 10 msec.

Using the principles described for forming the transistor 400, core and no-core transistors may be formed on a same substrate, with the gate structures of the core transistors oriented in a first direction and the gate structures of the non-core transistors oriented in a different second direction. The core transistors may be formed with a smaller space between optional halo regions under the gate structure, while the non-core transistors may have a larger space between the optional halo regions under the gate structure. One approach that might be used to form halo regions with different spacing would be to mask off one subset of transistors on a substrate and perform a first halo implant at a small first tilt angle directed under the gate structures of the exposed transistors. This first implant would be expected to result in halo regions that are spaced relatively far apart under the gate structures. The first subset of transistors would then masked off and a second different subset of transistors would be exposed. A second halo implant would be directed under the gate structures of the second subset of transistors at a larger second tilt angle. This second first implant would result in halo regions that would be relatively closely spaced. Thus the first subset of transistors may be non-core transistors and the second subset of transistors may be core transistors.

In some example of the disclosure, as described in greater detail below, one or more masking steps may be eliminated by orienting the gate structures of the core transistors in a different direction than the gate structures of the non-core transistors, e.g. rotated 90°. The angle of the halo implant may set at the larger tilt angle. Those transistors with gate structures having long axes oriented normal to the direction of tilt receive a halo implant that penetrates relatively far under the gate structure, resulting in closely spaced halo regions. Those transistors with gate structures having long axes oriented parallel to the direction of tilt receive a halo implant that penetrates relatively little under the gate structure, resulting in halo regions spaced farther apart. Thus closely spaced halo regions are formed for core transistors and further-spaced halo regions are formed for non-core transistors. The following description provides additional details of such a method. Additional details may be found in U.S. Pat. No. 7,994,009, incorporated herein by reference in its entirety.

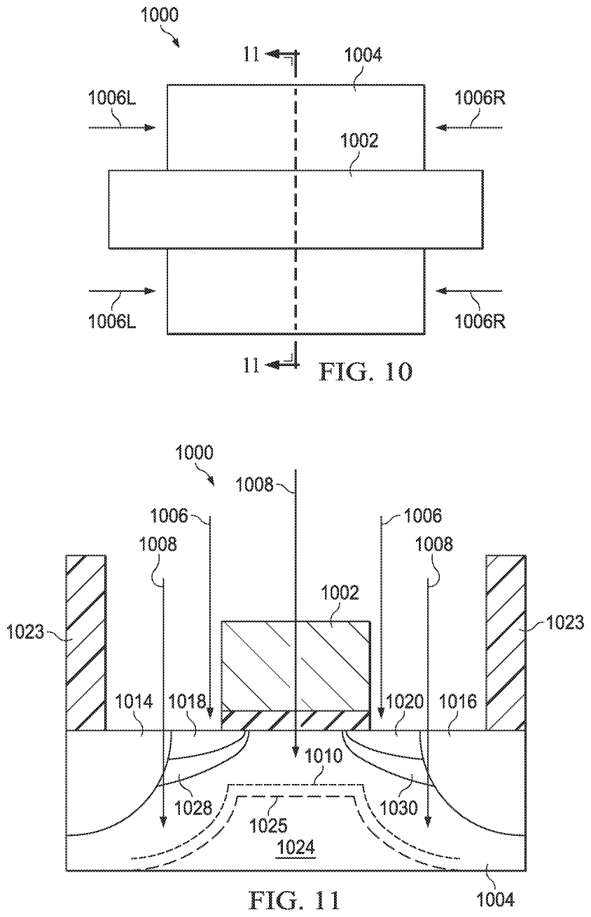

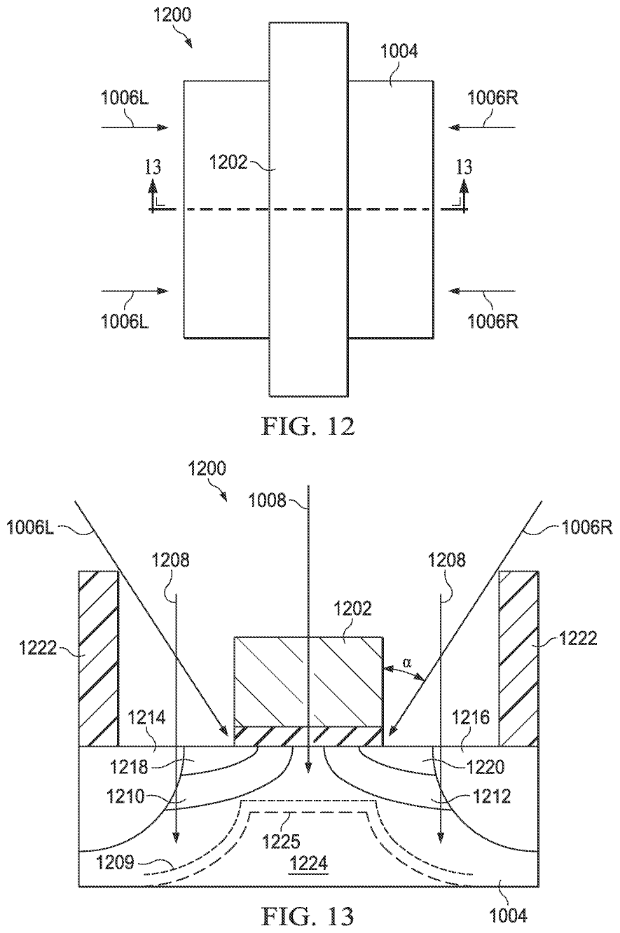

FIGS. 10 and 11 depict non-core transistor 1000, and FIGS. 12 and 13 depict core transistor 1200 that may be formed on a common die according to the methods described herein. In an example, the transistors 1000, 1200 are oriented such that a long axis of a gate structure 1002 of the non-core transistor 1000 (FIG. 10) is oriented perpendicular to a long axis of a gate structure 1202 of the core transistor 1200 (FIG. 12). The gate structures 1002 and 1204 may each include a doped polysilicon gate or metal gate over a gate dielectric such as silicon oxide. In other examples, the transistors 1000, 1200 may be formed with different relative orientations. The orientations between the core and non-core transistors enables different implant angles and numbers of rotations to impact the respective core and non-core transistors in different ways.

FIGS. 10 and 11 thus depict respective top and side cross-sectional views of the non-core transistor 1000 formed in or over a substrate 1004. FIG. 10 depicts a first optional halo implant step represented by a halo implant beam vector 1006L in which a P-type halo dopant for an NMOS transistor (N-type dopant for a PMOS transistor) is implanted adjacent to the gate 1002 at a first rotation of the substrate 1004. A halo implant beam vector 1006R represents a second optional halo implant step in which the halo dopant is implanted adjacent to the gate 1002 at a second rotation of the substrate 1004. Typically, the beam direction is fixed, and a processing platform rotates the substrate 1004 relative to a single beam. Thus the halo implant beam vectors may be collectively referred to as a halo implant beam vector 1006. The halo implant beam vector 1006 includes a component parallel to the surface of the substrate 1004 (“horizontal component”) and a component perpendicular, or normal, to that surface (“vertical component”). The halo implants may be implanted at a tilt angle of the halo implant beam vector 1006 in a range between 0 and 45 degrees with respect to the surface normal, and with the horizontal component of the halo implant beam 1006 parallel to the long axis of the gate 1002. The halo implant may be implemented with one rotation or two rotations, e.g. one or both of the beam vectors 1006L, 1006R. Referring to FIG. 11, a well 1024 was formed by implanting a well dopant into the substrate in an implantation step at an earlier stage of manufacturing. Also shown is a peak concentration profile 1025 for a channel dopant previously implanted in the well 1024. The well 1024 may be P-type, e.g. doped with boron, or N-type, e.g. doped with phosphorous, depending on the transistor type. A peak concentration profile 1025 of a channel dopant previously implanted in the well 1024 qualitatively describes the depth of the peak concentration of the channel dopant. The channel dopant is selected corresponding to the transistor type, as previously described. Referring without implied limitation to the example of the P-type well, the transistor 1000 also includes N-type source/drain regions 1014, 1016 and source/drain extensions 1018, 1020 that are formed in an implantation step not explicitly shown. The source/drain region 1014 and source/drain extension 1018 may be referred to as a “source region” when further elaboration is unnecessary. Similarly the source/drain region 1016 and source/drain extension 1020 may be referred to as a “drain region” when further elaboration is unnecessary. The optional halo implant is represented by the beam vector 1006 while recognizing the halo dopant implant may be performed in two steps with two different rotations. The halo implant, if performed, forms halo regions 1028 and 1030 such that these regions are spaced apart by a distance under the gate structure 1002. Moreover the source/drain extension 1018 in the current example is completely surrounded by the halo region 1028 and source/drain region 1014, and the source/drain extension 1020 is completely surrounded by the halo region 1030 and source/drain region 1016. Also depicted in FIG. 11 is photoresist 1022 for masking areas from which the implants are to be omitted.

A through-gate co-implant 1008 is directed to the gate structure 1002 and open areas adjacent the gate structure 1002. For example, the through-gate co-implant 1008 is implanted with sufficient energy to penetrate the gate structure 1002 into the substrate 1004 to provide a peak concentration profile 1010 of the diffusion control species in the well 1024 beneath gate structure 1002. Similar to the peak concentration profile 1025, the peak concentration profile 1010 qualitatively describes the depth of the peak concentration of the co-implant species. As described previously, the through-gate co-implant 1008 includes carbon and/or, nitrogen and/or fluorine. Because the substrate 1004 is unmasked near the gate structure 1002, the co-implant 1008 also may be implanted into the substrate 1004 in the areas on each side of the gate structure 1002. Because the co-implant 1008 is not impeded by the gate structure 1002 in these areas the co-implant species is implanted deeper into the substrate under the source/drain extensions 1018, 1020, resulting in the observed peak concentration profile 1025 in which the peak concentration is closer to the surface under the gate structure 1002, and further from the surface under the source/drain regions 1014, 1016.

FIGS. 12 and 13 depict top and side cross-sectional views of the core transistor 1200, showing an example of through-gate implants and halo implants that may be used to form the transistor 1200. The core transistor 1200 includes the gate structure 1202 formed on the substrate 1004, such as described herein. The first halo implant step 1006L is performed at the first rotation, and the second halo implant step 1006R is performed at the second rotation.

Referring to FIG. 13, a well 1224 has been formed at an earlier stage of manufacturing, and a peak concentration profile 1225 describes a channel dopant previously implanted in the well 1224. The well 1224 may be a Pwell or an Nwell depending on the dopant species used to define transistor polarity The core transistor 1200 also includes source/drain regions 1214, 1216 and source/drain extensions 1218, 1220. As shown in FIG. 13, through-gate co-implants 1008 are implanted into the gate structure 1202 with sufficient energy to penetrate the gate structure 1202 and enter into the well 1224. The through-gate co-implants 1008 thus provide a concentration of the diffusion control species having a peak concentration profile 1209 beneath the gate structure 1202 and extending under the source/drain regions 1214, 1216.

In FIG. 13 the tilt angle of the halo implant beam is represented as a. The (optional) halo implants 1006L, 1006R are shown having the tilt angle a with respect to the surface normal of the substrate 1004 to form halo regions 1210, 1212. As described previously, in various examples the a may be in a range from about 0 degrees (no tilt) to about 45 degrees, with the horizontal component of the implant beam perpendicular to the gate structure 1202 (see FIG. 12). As described previously, the halo implant 1006L takes place at a first rotation of the substrate 1004 and the halo implant 1006R takes place at a second rotation of the substrate 1004, and one or both rotations may be used. FIG. 13 also includes a mask of photoresist 1222 for masking areas from which the implants are to be omitted. Different from the transistor 1000, when the tilt angle is high enough, the halo implant is blocked by the gate structure such that only the halo region 1210 is formed by the halo implant 1006L, and only the halo region 1220 is formed by the halo implant 1006R.

In one example, the through-gate co-implant 1008 may be performed so that the non-core transistor 1000 and the core transistor 1200 each receive the same concentration of co-implant species beneath respective gate structures 1002, 1202. This result may be obtained by implanting the co-implant species at a tilt angle of about 0 degrees and with a single rotation, or at a tilt angle within a range between about 0 and about 45 degrees with four rotations at 90° increments. As a result, threshold voltage mismatch may be improved across different transistor devices.

In another example, the through-gate co-implant 1008 may be performed to provide different concentrations of the through-gate co-implant species beneath the gate structure 1002 and the gate structure 1202. For example, the through-gate co-implant species may be implanted at a tilt angle in a range between about 5 and about 45 degrees with 2 rotations 180 degrees apart so that the core transistor 1200 receives a greater concentration of co-implant species in the channel region beneath the gate structure 1202 than the non-core transistor 1000 receives in the channel region beneath the gate structure 1002. In yet another example, the through-gate co-implant species implant 1008 may be implemented with two rotations about 90 degrees apart so that core transistor 1200 receives less through-gate co-implant compared to the non-core transistor 1000.

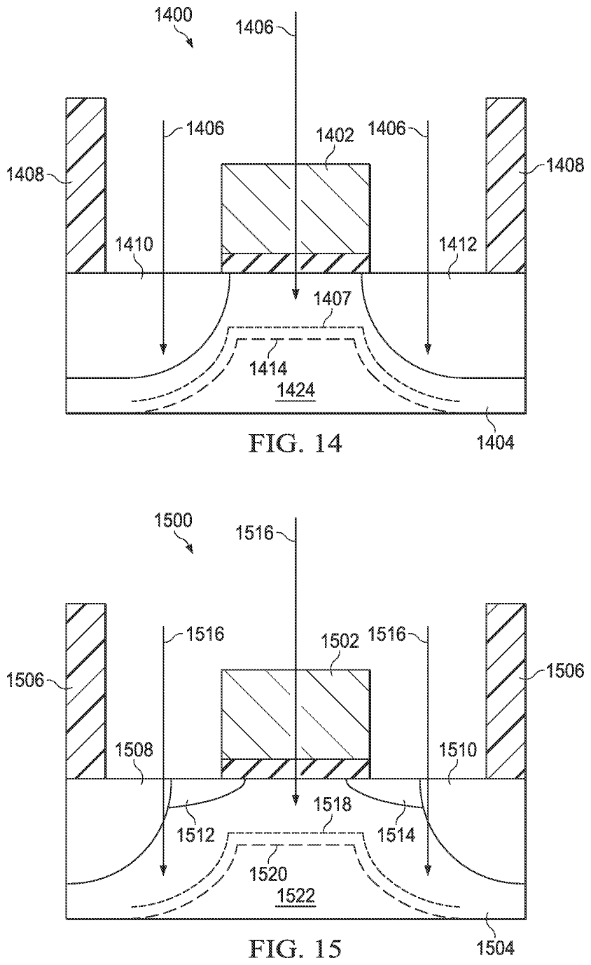

FIG. 14 is a cross-sectional view of another example of a transistor 1400 formed in part by through-gate implantation of a diffusion control species. In the example of FIG. 14, the transistor 1400 is formed without halo regions and without source drain extensions. The transistor 1400 includes a gate structure (e.g., a doped polysilicon gate or metal gate over gate oxide) 1402 formed on a substrate 1404 over a well 1424. The well 1424 may be a Pwell or an Nwell depending on the polarity of the transistor 1400. For the example of an NMOS transistor 1400, a P-type dopant is implanted to form the well 1424. A peak concentration profile 1414 of a channel dopant previously implanted in the well 1424 qualitatively describes the depth of the peak concentration of the channel dopant. During fabrication, photoresist 1408 is provided for masking areas from which the implants are to be omitted. Source/drain regions 1410, 1412 are formed in the substrate 1404 between the gate structure 1402 and the photoresist 1408. In the example of FIG. 14, the through-gate co-implant 1406 (e.g., carbon and/or, nitrogen and/or fluorine) is implanted with sufficient energy to penetrate the gate structure 1402 into the well 1424 beneath the gate. The implanted through-gate co-implant 1406 is characterized by a peak concentration profile 1407 that qualitatively describes the depth of the peak concentration of the co-implant species. The co-implant species may be implanted more deeply into the substrate next to the gate structure 1402, resulting in the illustrated concentration profile 1407 in which the peak concentration is at a greater depth below the substrate surface under the source/drain regions 1410, 1412 that under the gate structure 1402.

FIG. 15 is a cross-sectional view of yet another example of a transistor 1500. In the example of FIG. 15, the transistor 1500 is formed without halo regions, but includes LDD drain extensions 1512, 1514. The transistor 1500 includes a gate structure (e.g., a doped polysilicon gate or metal gate over gate oxide) 1502 formed over a well 1522. The well 1522 may be a Pwell or an Nwell depending on the polarity of the transistor 1500. Photoresist 1506 is also provided for masking areas from which the implants are to be omitted. The transistor 1500 also includes source/drain regions 1508, 1510 respectively connected to the source/drain extensions 1512, 1514. A peak concentration profile 1520 of a channel dopant previously implanted in the well 1522 qualitatively describes the depth of the peak concentration of the channel dopant. In the example of FIG. 15, a through-gate co-implant 1516 of a diffusion control species (e.g., carbon and/or, nitrogen and/or fluorine) is implanted with sufficient energy to penetrate the gate structure 1502 into the well 1522, forming a concentration profile with a peak concentration profile 1518. The co-implant 1516 also may be implanted into the substrate in the areas on each side of the gate structure 1502, resulting in the illustrated profile.

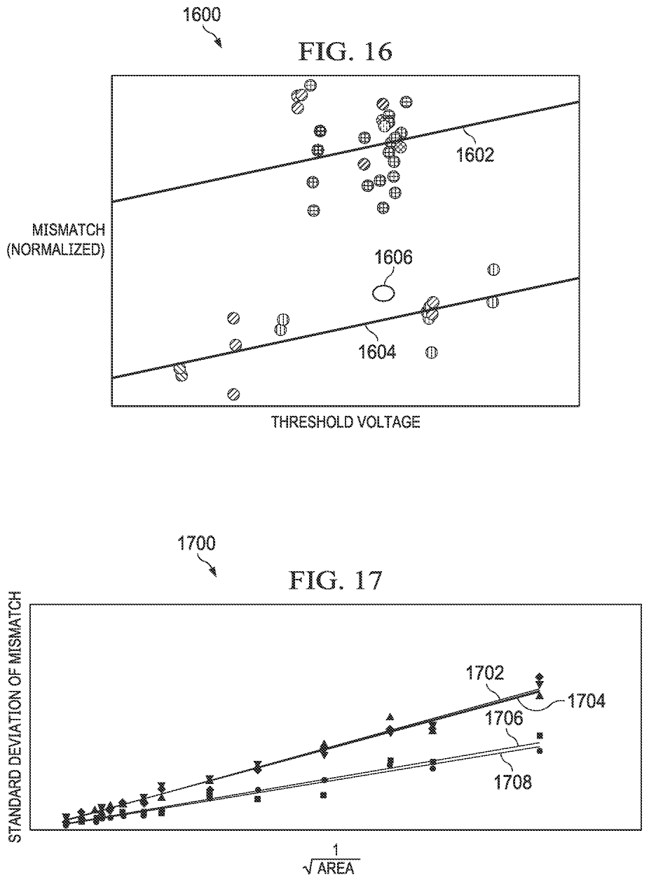

FIG. 16 is a graph 1600 depicting mismatch versus threshold voltage for transistors fabricated according to different methods. A curve 1602 is fit to data for representing transistor threshold voltage mismatch as a function of threshold voltage for a set of NMOS transistors fabricated according to a baseline approach. Another curve 1604 is fit to data for representing transistor threshold voltage mismatch as a function of threshold voltage for another set of NMOS transistors fabricated according to the approach described herein. Also plotted in the graph 1600 is a target value 1606 defined by a threshold voltage mismatch specification. The transistors produced according to the approach described herein meet the mismatch specification whereas those produced according to existing methods fail to meet the specification.

FIG. 17 is a graph 1700 depicting standard deviation of mismatch versus area^{-1/2} for different size non-core NMOS transistors fabricated according to different methods. In particular, the graph 1700 includes plots 1702 and 1704 for different size NMOS transistors fabricated according to baseline methods. Plots 1706 and 1708 represent mismatch characteristics for NMOS transistors made according to the approach disclosed herein with through-gate co-implants. In each of the plots, 1702, 1704, 1706 and 1708, the slope of the lines represents threshold voltage mismatch. Accordingly, the graph demonstrates that NMOS transistors that include a through-gate co-implant, as described herein, exhibit significant improvement in threshold voltage mismatch. As a result of having linear mismatch, transistor mismatch may remain fixed across area enabling the size of many MOS transistors to be reduced, which affords an increase in device density for IC's. This is particularly advantageous for analog non-core transistors that tend to vary widely in size across an IC.

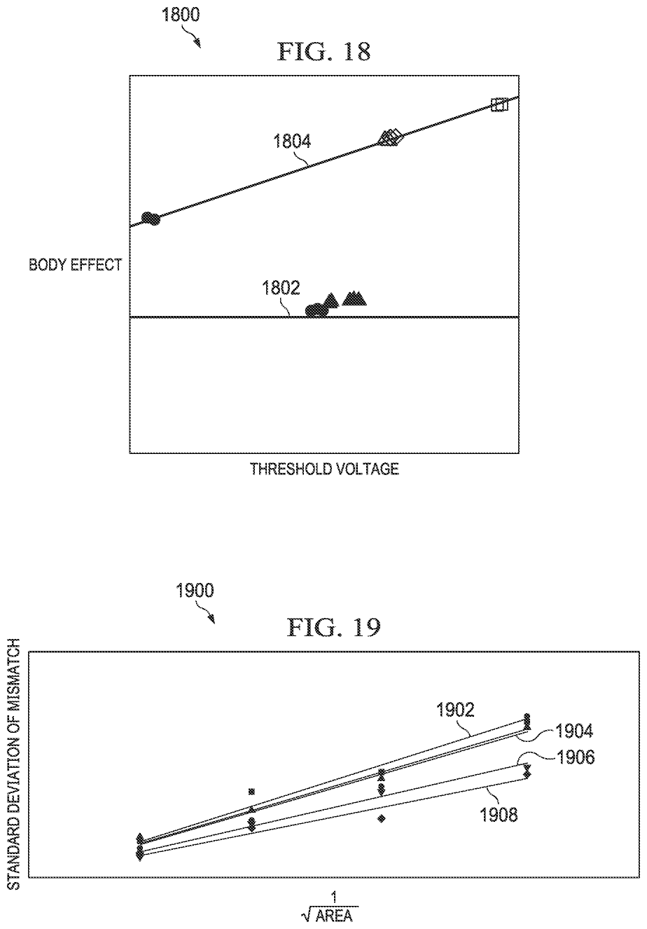

FIG. 18 is a graph 1800 depicting body effect versus threshold voltage for transistors fabricated according to different methods. In the graph 1800, a first set of transistors, indicated at 1802, exhibits a relatively constant body effect over a range of threshold voltages, which is indicative of a generally flat dopant profile in such transistors. In contrast, another set of transistors fabricated with a through-gate co-implant, indicated at 1804, exhibit a higher body effect, which is indicative of a more abrupt retrograde profile, as described herein.

FIG. 19 is a graph 1900 depicting standard deviation of mismatch versus area^{-1/2} for different size core (e.g., short channel) NMOS transistors fabricated according to different methods. In particular, the graph 1900 includes plots 1902 and 1904 for different size core NMOS transistors fabricated according to baseline methods. Plots 1906 and 1908 represent mismatch characteristics for core NMOS transistors made with through-gate co-implants as disclosed herein. In each of the plots, 1902, 1904, 1906 and 1908, the slope of the lines represents threshold voltage mismatch. Accordingly, the graph 1900 demonstrates that core NMOS transistors that include a through-gate co-implant, as described herein, exhibit significant improvement in threshold voltage mismatch as compared to transistors without the through-gate implant.

Disclosed aspects can be used to form semiconductor die that may be integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, gates, sources, drains, conductive lines, conductive vias, etc. Moreover, the semiconductor die can be formed from a variety of processes including CMOS, BiCMOS and MEMS.

Modifications are possible in the described embodiments, and other embodiments are possible, within the scope of the claims.

What is claimed is:

1. An integrated circuit (IC), comprising:
a metal oxide semiconductor (MOS) transistor formed in a semiconductor substrate, comprising:
a gate structure formed over a surface of the substrate;
source and drain regions having a first conductivity type formed in the substrate on both sides of the gate structure; and
a well region having a second opposite conductivity type between the source and drain regions under the gate structure, the well region including a well dopant and a through-gate co-implant species, the well dopant and the co-implant species having a retrograde profile extending from the surface of the substrate into the well region.

2. The IC of claim 1, wherein the through-gate co-implant species comprises one or more of carbon, fluorine and nitrogen.

3. The IC of claim 1, wherein the well dopant comprises one or more of boron and indium, or one or more of phosphorous, arsenic and antimony.

4. The IC of claim 1, wherein the MOS transistor is an N-type MOS transistor and the well dopant comprises a P-type dopant.

5. The IC of claim 1, wherein the co-implant species has a peak concentration profile that is spaced apart from the substrate surface by a first distance directly under the gate structure, and spaced apart from the substrate surface by a second greater distance directly below the source and drain regions.

6. The IC of claim 1, wherein a well dopant species of the well region has a peak concentration profile that is spaced apart from the substrate surface by a first distance directly under the gate structure, and spaced apart from the substrate surface by a second greater distance directly below the source and drain regions.

7. The IC of claim 1, further comprising halo regions formed on both sides of the gate structure.

8. The IC of claim 1, further comprising source/drain extension regions formed between the source and drain regions.

9. The IC of claim 8, wherein the source/drain extension regions have a lower dopant concentration that the source and drain regions.

10. The IC of claim 1, wherein the gate structure comprises polysilicon over a gate oxide layer.

11. The IC of claim 1, wherein the MOS transistor comprises a core MOS transistor having a gate dielectric with a first thickness and a non-core MOS transistor having a gate dielectric with a second greater thickness, the through-gate co-implant species being in the substrate beneath the gate structure between the drain region and the source region of each of the core MOS transistor and the non-core MOS transistor.

12. A method of forming an integrated circuit, the method comprising:
forming a gate structure on a surface of a substrate;
forming source/drain regions in the substrate on either side of the gate structure;
implanting a dopant into the substrate to establish a channel region;
implanting a co-implant species through the gate structure into the substrate; and
annealing after implanting both the dopant and the co-implant species to provide a retrograde profile of the dopant in the substrate beneath the gate structure.

13. The method of claim 12, wherein the co-implant species is implanted at an energy level within a range from approximately 10 keV to approximately 40 keV.

14. The method of claim 12, wherein the dopant is implanted after the co-implant species.

15. The method of claim 12, further comprising forming source/drain extension regions in the substrate adjacent both sides of the gate structure between the source region and the drain region.

16. The method of claim 15, wherein the dopant is implanted through the gate structure into the channel region between the source/drain extension regions.

17. The method of claim 12, further comprising forming halo regions in the substrate between the source/drain regions.

18. The method of claim 12, wherein
the dopant comprises a boron species, and
the co-implant species comprises carbon.

19. A transistor, comprising:
a substrate;
a gate structure formed over a surface of the substrate, the gate structure including a gate electrode over a dielectric layer;
source/drain extension regions formed in the substrate adjacent both sides of the gate structure;
source/drain regions formed in the substrate adjacent both sides of the gate structure, the source/drain regions being spaced apart further than the source/drain extension regions;
halo regions formed on both sides of the gate structure, each halo region touching the gate dielectric, one of the source/drain regions and one of the source/drain extension regions; and
dopant and through-gate co-implant species in the substrate between the drain region and the source region, the dopant having a retrograde profile that defines a concentration of the dopant in the substrate along a direction orthogonal to the surface of the substrate, the concentration of the dopant increasing from the surface of the substrate to a location having a peak concentration, which is spaced from the surface of the substrate, and decreasing from the location having the peak concentration along the direction.

20. The transistor of claim 19, wherein
the through-gate co-implant species comprises one of carbon, fluorine or nitrogen, and
the dopant comprises one of boron or phosphorous.

21. An integrated circuit (IC), comprising:
a first transistor formed in or over a semiconductor substrate, comprising:
a first source region and a first drain region both having a first conductivity type formed in the substrate;
a first gate structure formed over a surface of the substrate between the first source region and the first drain region, the first gate structure having a long axis oriented laterally over the substrate in a first direction;
a first well region having a second opposite conductivity type under the first gate structure and between the first source region and the first drain region, the first well region including a well dopant and a first co-implant species, the well dopant and the first co-implant species having a retrograde profile extending from the surface of the substrate into the first well region;
a second transistor formed in or over the semiconductor substrate, comprising:
a second source region and a second drain region both having the first conductivity type formed in the substrate;
a second gate structure formed over the surface of the substrate between the second source region and the second drain region, the second gate structure having a long axis oriented laterally over the substrate in a second direction about orthogonal to the first direction; and
a second well region under the second gate structure and between the second source region and the second drain region, the second well region including the well dopant and a second co-implant species, the well dopant and the second co-implant species having a retrograde profile extending from the surface of the substrate into the first well region.

22. The IC of claim 21, further comprising first halo regions in the substrate between the first source region and the first drain region and second halo regions in the substrate between the second source region and the second drain region, the first and second halo regions having the second conductivity type, the first halo regions laterally spaced apart under the first gate structure by a first distance, and the second halo regions laterally spaced apart under the second gate structure by a second greater distance.

23. The IC of claim 21, wherein the first gate structure includes a first gate dielectric having a first thickness, and the second gate structure includes a second gate dielectric having a second greater thickness.

24. The IC of claim 21, wherein each of the first and second co-implant species is selected from the group consisting of carbon, nitrogen and fluorine.

25. The IC of claim 21, wherein the first conductivity type is N-type and the second conductivity type is P-type.
